(19) United States
(12) Patent Application Publication
(10) Pub. No.: US 2007/0069395 A1
(43) Pub. Date: Mar. 29, 2007

(54) Image sensor module, camera module using the same, and method of manufacturing the camera module

(75) Inventors: Ho Kyoum Kim, Suwon-si (KR); Hyung Chan Kwak, Yongin-si (KR); Dong Min Shin, Suwon-si (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon-si (KR)

(21) Appl. No.: 11/512,221

(22) Filed: Aug. 30, 2006

(30) Foreign Application Priority Data
Sep. 27, 2005 (KR) 10-2005-0089837

(51) Int. Cl. H01L 23/48

(52) U.S. Cl. 257/780

(57) ABSTRACT

The present invention relates to an image sensor module including a flexible printed circuit board (FPCB) having a window; and an image sensor that is formed to have the same size as the width of the FPCB and is attached on one surface of the FPCB, the image sensor including a light receiving section, which receives light passing through the window, and a signal processing section which processes signals generated by the light receiving section.

### CROSS-REFERENCE TO RELATED APPLICATIONS

The application claims the benefit of Korea Patent Application No. 2005-0089837 filed with the Korea Intellectual Property Office on Sep. 27, 2005, the disclosure of which is incorporated herein by reference.

### BACKGROUND OF THE INVENTION

1. Field of the Invention

The present invention relates to an image sensor module, which is used in digital cameras, mobile equipments, various monitoring devices or the like, a camera module using the same, and a method of manufacturing the camera module. In the image sensor module, process tolerance generated by an existing packaging method is minimized to prevent an optical axis from being shifted, which makes it possible to improve productivity.

2. Description of the Related Art

As the information communication technology rapidly develops, data communication speed is improved, and an amount of data communication is expanded. Further, an imaging device such as a CCD image sensor or CMOS image sensor is mounted on mobile electronic equipments such as mobile phones or notebooks, and thus image data as well as text data can be transmitted in real-time, the image data being taken by a camera module.

As a method of packaging an image sensor for camera, there are provided a flip-chip COF (Chip On Film) method, a wire-bonding COB (Chip On Board) method, and a CSP (Chip Scale Package) method, among which the COF method and the COB method are widely used.

The COB method is a similar process to that of an existing semiconductor production line and has higher productivity than other packaging methods. However, since wire should be used for the connection with a PCB, the size of a module increases and an additional process is needed. Therefore, a new packaging technique is required to reduce the size of chip, to enhance heat emission and electrical performance, and to improve reliability. Accordingly, a COF method emerges based on bumps having an external bonding projection.

In the COF method, a space for attaching wire is not needed. Therefore, the area of a package and the height of a lens barrel can be reduced. Further, since a thin film or flexible printed circuit board (FPCB) is used in the COF method, a reliable package which endures an external impact can be manufactured and the process thereof is relatively simplified. Moreover, the COF method satisfies such a tendency that signals are processed at high speed, high density is required, and multiple pins are needed.

The COF method is implemented as chip size wafer-scale packaging. However, the process cost thereof is expensive, and the correspondence to the due date is unstable. Therefore, the method has a limit as a method for image sensor.

Further, in a module using a mega-quality sensor to which various functions are added, the miniaturization of module, which has been a merit of the COF method, is not realized any more, because of the one-story structure. The module cannot but be designed to have a larger size than in the COB method.

Currently, a double-sided flexible printed circuit board (FPCB) is used so that a module can be designed to have a similar size to that in the COB method, which does not satisfy the miniaturization of module which is a merit of the COF method. Therefore, since the COB method tends to be frequently used, the design and process technique for realizing the miniaturization of module are required.

In a camera module, a lens and a light receiving surface of an image sensor mounted on a wiring board need to be assembled so that the optical axis of the lens is accurately positioned in the center of the image sensor. However, in the existing methods of packaging a camera module including the COB method and the COF method, optical axis shifting can occur, which has influence on an image quality which is the most important for a camera module. Further, an optical axis is significantly shifted because of tolerances generated in the respective processes and tolerances of components composing the module.

Various methods are proposed in order to prevent an optical axis from being shifted. For example, related techniques are disclosed in Japanese Unexamined Patent Application Publication No. 2004-55574 and the like. In such techniques, however, the degree of difficulty in design is high, and process management is not easy.

Hereinafter, conventional camera modules using the COB method and the COF method, respectively, will be described with reference to accompanying drawings, and the problems thereof will be examined.

FIG. 1 is a diagram illustrating a camera module according to the COB packaging method. FIG. 1A is a diagram for explaining tolerance generated when a process is performed by the COB packaging method, and FIG. 1B is a diagram for explaining optical axis shifting which occurs due to the tolerance generated by the above method.

In the COB packaging method, a positioning PCB hole 310 is first processed on a PCB 300 for coupling with a housing 200, as shown in FIG. 1A. Then, after a die-bonding process is performed to attach an image sensor 320 on the PCB having the processed hole, a projection 210 of the housing 200 including a lens section is coupled and bonded to the PCB hole 310 of the PCB to which the image sensor 320 is bonded.

In such a COB packaging method, three types of tolerances are generated, and thus an optical axis passing through the lens section is not accurately positioned in a light receiving section of the image sensor. That is, size tolerance A, die-bonding position tolerance B, and size tolerance C are generated. The size tolerance A is size tolerance of the PCB hole 310 processed in the PCB for coupling with the housing 200. The die-bonding position tolerance B is generated when the image sensor 320 is shifted and attached at the time of die-bonding the image sensor 320. The size tolerance C is size tolerance of the projection 210 formed in the housing 200 for coupling with the PCB hole 310.

Because of tolerances accumulated by the above-described reason, optical axis shifting, tilting, and rotation occur so that the optical axis passing through the lens section is separated at a predetermined distance from the pixel center of the image sensor, as shown in FIG. 1B.

FIG. 2 is a diagram illustrating a conventional camera module according to the COF packaging method. FIG. 2A is a diagram for explaining the COF packaging method and tolerance generated when a process is performed by the COF packaging method, and FIG. 2B is a diagram for explaining optical axis shifting, tilting, and rotation which occur due to the tolerance generated by the above method.

In the COF packaging method, an image sensor 320 is first attached on one surface (lower surface) of an FPCB 300 provided with a window through which light passing through a lens section can be transmitted, as shown in FIG. 2A. An IR filter 330 having a predetermined size is attached on a surface (upper surface) opposite to one surface of the FPCB 300 having the image sensor 320 attached. Then, with the outer peripheral surface of the IR filter 330 being set to a guide surface, an inner peripheral surface of a lower opening of the housing 200 including the lens section is closely coupled and bonded to the outer peripheral surface.

In such a COF packaging method, two types of tolerances are generated so that the optical axis passing through the lens section is not accurately positioned in a light receiving section of the image sensor. That is, IR filter size tolerance and IR filter position tolerance are generated. The IR filter size tolerance is generated when the outer peripheral surface of the IR filter 330, guiding the housing 200, is processed, and the IR filter position tolerance is generated when the IR filter 330 is shifted and attached at the time of attaching the IR filter 330 on the FPCB 300.

Because of tolerances accumulated by the above-described reason, optical axis shifting, tilting, and rotation occur so that the optical axis passing through the lens section is separated at a predetermined distance from the pixel center of the image sensor, as shown in FIG. 2B.

In the conventional COF packaging method, elements such as a multilayer ceramic capacitor (MLCC) and the like cannot be mounted so as to be positioned inside the housing of the camera module because of the IR filter attached on the FPCB, but are inevitably mounted so as to be positioned outside the housing or on the same surface as the surface on which the image sensor is attached. As a result, the size of a required FPCB becomes so large that the overall size of the image sensor module becomes large.

Further, in the image sensor module according to the conventional COF packaging method, if the camera module is limited to a constant size by the request of a user, active or passive elements including the multilayer ceramic capacitor should be inevitably removed from the image sensor module in order to design a product within the limited size of the camera module. At this time, if the multilayer ceramic capacitor is removed from the image sensor module, screen noise occurs. However, such problems are inevitable in order to reduce the overall size of the camera module including the housing.

### SUMMARY OF THE INVENTION

An advantage of the present invention is that it provides an image sensor module and a camera module using the same, in which an optical axis passing through a lens section is accurately positioned in a light receiving section of an image sensor, thereby preventing optical axis shifting, tilting, and rotation. Therefore, percent defective related to high resolution and resolution can be reduced, and the size of the module can be reduced to achieve the miniaturization.

Another advantage of the invention is that it provides a method of manufacturing the camera module.

Additional aspects and advantages of the present general inventive concept will be set forth in part in the description which follows and, in part, will be obvious from the description, or may be learned by practice of the general inventive concept.

According to an aspect of the invention, an image sensor module includes a flexible printed circuit board (FPCB) having a window; and an image sensor that is formed to have the same size as the width of the FPCB and is attached on one surface of the FPCB, the image sensor including a light receiving section, which receives light passing through the window, and a signal processing section which processes signals generated by the light receiving section.

According to another aspect of the invention, the FPCB is a rigid flexible printed circuit board (RFPCB) or a double-sided flexible printed circuit board (FPCB).

According to a further aspect of the invention, at least one more electrical part is attached on the other surface of the FPCB having the image sensor attached thereon.

According to a still further aspect of the invention, the electrical parts are mounted so as to be positioned between the window and the outer peripheral surface of the image sensor.

According to a still further aspect of the invention, the electrical parts include at least one more multilayer ceramic capacitor (MLCC).

According to a still further aspect of the invention, a camera module includes a lens section; a housing supporting the lens section; and an image sensor module composed of an FPCB that has the substantially same size of an outer peripheral surface as the inner peripheral surface of the lower opening of the housing and is attached on the inner peripherals surface of the lower opening of the housing; and an image sensor module that is formed to have the same size as the width of the FPCB having a window and is attached on the rear surface of the FPCB.

According to a still further aspect of the invention, the FPCB is a RFPCB or double-sided FPCB.

According to a still further aspect of the invention, at least one more electrical part is attached on a surface opposite to the rear surface of the FPCB having the image sensor attached thereon.

According to a still further aspect of the invention, the electrical parts are mounted so as to be positioned between the window and the outer peripheral surface of the image sensor.

According to a still further aspect of the invention, the electrical parts include at least one more multilayer ceramic capacitor (MLCC).

According to a still further aspect of the invention, the camera module further includes an IR cut filter that is mounted inside the housing in order to receive only visible light from the incident light passing through the lens section.

According to a still further aspect of the invention, the camera module further includes an IR cut filter that is attached on a surface opposite to the rear surface of the FPCB having the image sensor attached thereon, in order to receive only visible light from the incident light passing through the lens section.

According to a still further aspect of the invention, a method of manufacturing a camera module includes attaching an image sensor on the rear surface of an FPCB provided with a window, the image sensor having the substantially same size as the width of the FPCB, in order to provide an image sensor module; and coupling and attaching the image sensor module to the inner peripheral surface of a lower opening of a housing supporting a lens section from the direction opposite to the rear surface of the FPCB having the image sensor attached, with the outer peripheral surface of the image sensor being set to a guide surface.

According to a still further aspect of the invention, a RFPCB or double-sided FPCB is used as the FPCB.

According to a still further aspect of the invention, the method further includes, prior to coupling the image sensor module to the inner peripheral surface of the lower opening of the housing supporting the lens section, mounting at least one more electrical part on the surface opposite to the rear surface of the FPCB having the image sensor attached, such that at least one more electrical part is positioned between the window and the outer peripheral surface of the image sensor.

According to a still further aspect of the invention, the method further includes, prior to coupling the image sensor module to the inner peripheral surface of the lower opening of the housing supporting the lens section, mounting an IR cut filter in the housing, in order to receive only visible light from the incident light passing through the lens section.

According to a still further aspect of the invention, the method further includes, prior to coupling the image sensor module to the inner peripheral surface of the lower opening of the housing supporting the lens section, attaching an IR cut filter on the surface opposite to the rear surface of the FPCB having the image sensor attached, in order to receive only visible light from the incident light passing through the lens section.

According to a still further aspect of the invention, attaching the image sensor on the rear surface of the FPCB is performed by any one of a method in which an anisotropic conductive film (ACF) is inserted between the rear surface of the FPCB and the image sensor and is then pressed, a method in which a non-conductive paste (NCP) is put between the rear surface of the FPCB and the image sensor and is then pressurized, and a method using an ultrasonic wave.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIGS. 1A and 1B are diagrams illustrating a camera module according to a conventional COB packaging method, FIG. 1A being a diagram for explaining tolerance generated when a process is performed by the COB packaging method and FIG. 1B being a diagram for explaining optical axis shifting which occurs due to the tolerance caused by the method;

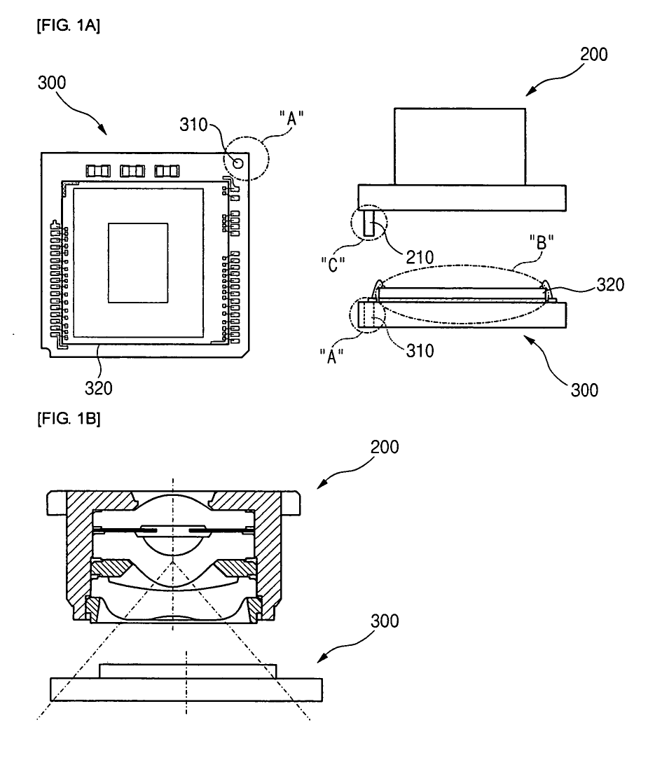

FIGS. 2A and 2B are diagrams illustrating a camera module according to a conventional COF packaging method, FIG. 2A being a diagram for explaining a process by the COF packaging method and tolerance generated when the process is performed and FIG. 2B being a diagram for explaining optical axis shifting which occurs due to the tolerance caused by the method;

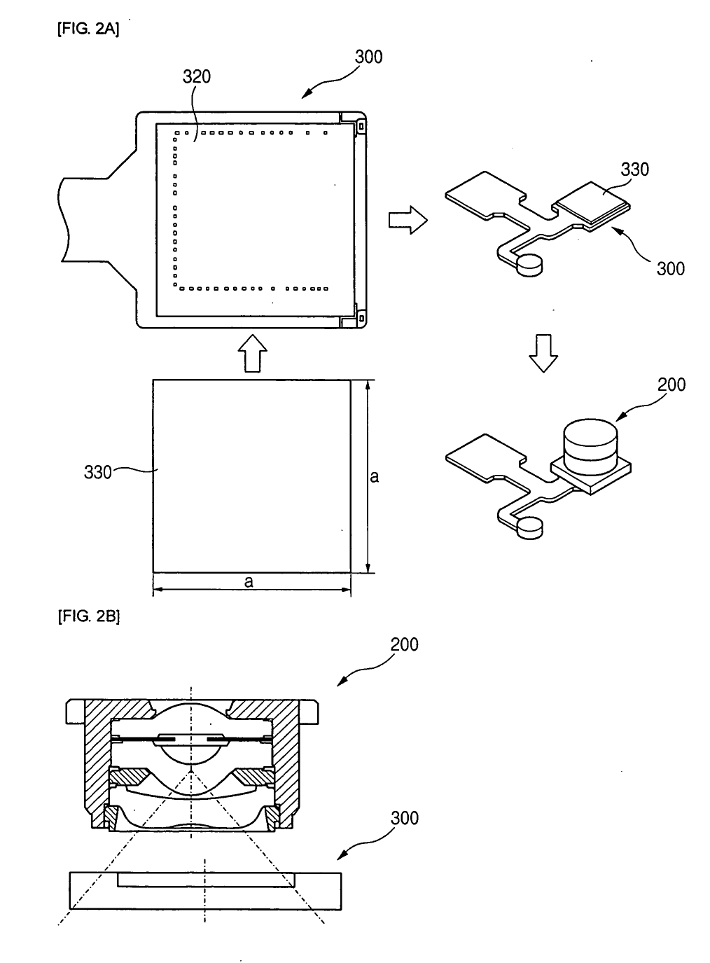

FIG. 3 is an exploded perspective view of an image sensor module and a camera module including the same according to the present invention;

FIG. 4 is a sectional view of the camera module according to the invention; and

FIG. 5 is a process view illustrating a method of manufacturing the camera module according to the invention.

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to the like elements throughout. The embodiments are described below in order to explain the present general inventive concept by referring to the figures.

Hereinafter, preferred embodiments of the present invention will be described in detail with reference to the accompanying drawings.

[Image Sensor Module and Camera Module]

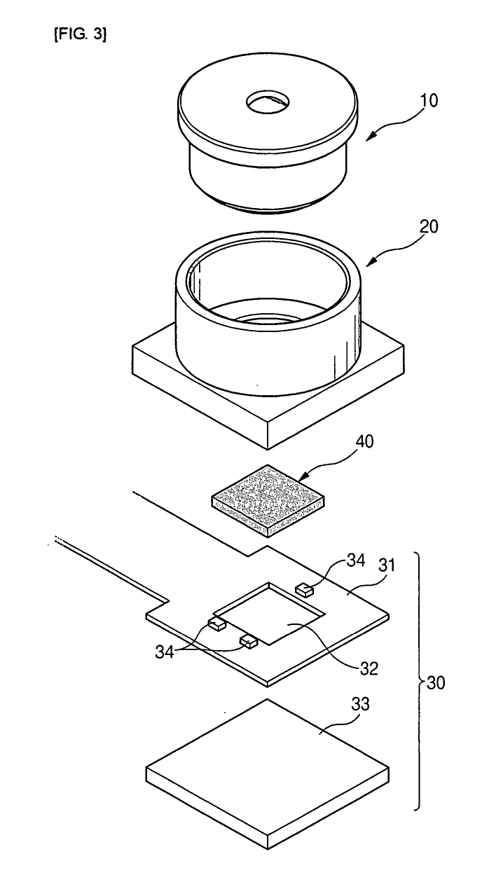

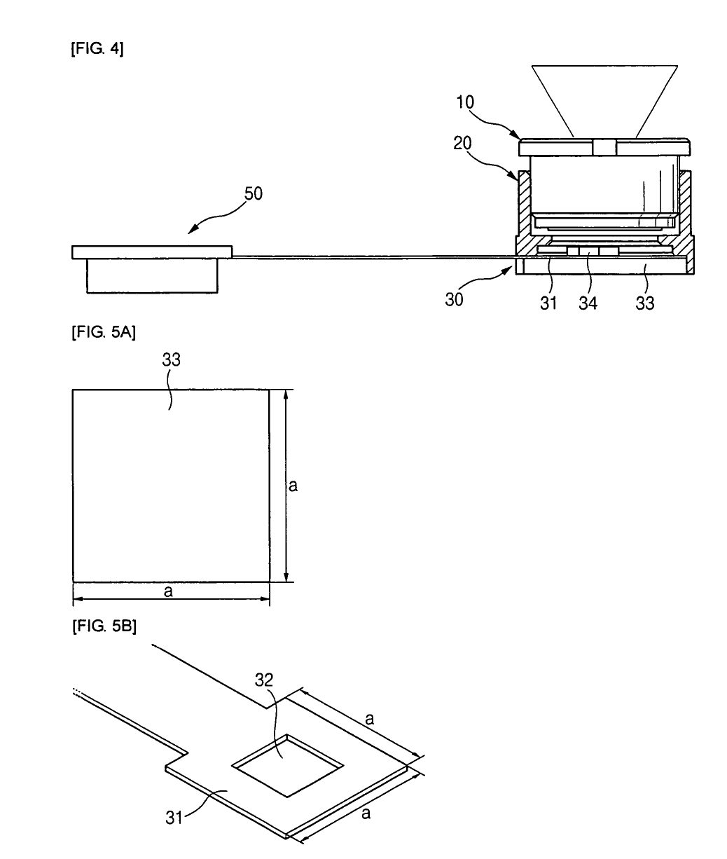

FIG. 3 is an exploded perspective view of a camera module including an image sensor module according to the invention, and FIG. 4 is a sectional view of the camera module.

As shown in FIGS. 3 and 4, the camera module according to the invention is composed of a lens section 10, a housing 20 into which the lens section 10 is inserted from the upper opening thereof so as to be mounted, and an image sensor module 30 which is coupled to the lower opening of the housing 20.

The housing 20 as a typical support has the openings formed in the upper and lower portions thereof, to which the lens section 10 and the image sensor module 30 to be described below are respectively coupled. Particularly, on the inner peripheral surface of the housing at the lower opening thereof, a guide projecting toward the inside of the housing is formed so as to serve as a position determining section when the housing is coupled to the image sensor module 30.

The lens section 10, which is inserted and coupled to the upper opening of the housing 20, serves as a lens holder and is formed of resin such as polycarbonate or the like. In the bottom portion thereof which is inserted into the housing 20, an aperture, a condensing lens and the like are installed. The aperture defines a path of light passing through the condensing lens, and the light passing through the aperture is received in a receiving section of an image sensor by the condensing lens. On the upper surface of the lens section 10, IR-coated glass is attached so as to prevent foreign substances from penetrating into the aperture or condensing lens.

The image sensor module 30 coupled to the lower opening of the housing 20 includes an FPCB 31 provided with a window 32 for transmitting light passing through the lens section 10 and an image sensor 33 receiving and processing the light passing through the window 32, the image sensor 33 being attached on the FPCB 31. Further, one end of the FPCB 31 is connected to a connector 40.

As one example of the FPCB 31, a resin board formed of polyimide having flexibility may be used. When a double-sided flexible printed circuit board (FPCB) or a rigid flexible printed circuit board (RFPCB) is used as the FPCB 31, at least one more electric part 34 can be mounted on a surface (upper surface) opposite to one surface (lower surface) of the FPCB 31 on which the image sensor 33 is attached. Therefore, it is possible to reduce the overall size of the image sensor module.

The image sensor 33 having the same size as the width of the FPCB 31 is attached on one surface of the FPCB 31. The image sensor 33 is composed of a light receiving section, which receives the light received from the condensing lens of the lens section 10 and performs photoelectric conversion, and a signal processing section which transmits signals generated by the light receiving section as image data. On a surface thereof which is attached on one surface of the FPCB 31, multiple electrode pads (not shown) are formed, each electrode pad having a bump formed thereon. At this time, when the image sensor 33 is attached by COF flip chip bonding, it is attached by using the bump projecting on the electrode pad and a non-conductive paste (NCP) instead of an anisotropic conductive film (ACF). The bump may be composed of any one of a stud-type bump, a non-electrolytic bump, and an electrolytic bump.

In the above-described image sensor module according to the invention, the size of the image sensor 33 is generally determined by the number of pixels. Therefore, the FPCB 31 is manufactured to have the same size as the image sensor 33 having a predetermined size, and the FPCB 31 and the image sensor 31 are attached to each other. That is, while the size of the FPCB is larger than that of the image sensor in the related art, the size of the FPCB is the same as that of the image sensor in the present invention.

In the present invention, the FPCB 31 is formed to have the same size as the image sensor 33 such that a surface of the image sensor 33 is used as a guide surface when the image sensor 33 is coupled to the housing 20. Then, it is possible to solve such a problem that an optical axis passing through the lens section is not accurately positioned in the light receiving section of the image sensor because of three types of tolerances generated in the conventional COB packaging method. Three types of tolerances are as follows. The first is size tolerance of a PCB hole formed in a PCB for coupling with a housing. The second is die-bonding position tolerance which is generated when an image sensor is shifted at the time of die-boding the image sensor. The third is size tolerance of a housing projection formed in a housing for coupling with a PCB hole. Further, it is possible to prevent optical axis shifting, tilting, and rotation, in which an optical axis passing through a lens section is separated at a predetermined distance from the pixel center of an image sensor because of two types of tolerances generated in the conventional COF packaging method. Two types of tolerances are as follows. The first is IR filter size tolerance which is generated when the outer peripheral surface of an IR filter for guiding a housing is processed. The second is IR filter position tolerance which is generated when the processed IR filter is shifted at the time of attaching the IR filter on the FPCB.

While the size of the FPCB is larger than that of the image sensor in the related art, the size of the FPCB is the same as that of the image sensor in the present invention. Therefore, it is possible to reduce the size of the image sensor module. As a result, it is possible to reduce the overall size of the camera module.

Further, in the related art, coupling and bonding is performed so that the inner peripheral surface of the lower opening of the housing including the lens section is closely attached on the outer peripheral surface of the IR filter attached on the FPCB, the outer peripheral surface serving as a guide surface. In the present invention, however, the outer peripheral surface of the image sensor is used as a guide surface for coupling the housing. Therefore, the IR filter can be mounted inside the housing or can be manufactured to have the substantially same size as the window formed in the FPCB, which is favorable for securing a space in terms of design. When a double-sided FPCB or RFPCB is used as the FPCB, at least one more electric part 34 such as a multilayer ceramic capacitor (MLCC) can be mounted on a surface (upper surface) opposite to one surface (lower surface) of the FPCB on which the image sensor is attached, at least one more electric part 34 being included inside the housing. Therefore, it is possible to reduce the overall size of the image sensor module, compared with the related art.

The electrical parts 34 mountable on the image sensor module 30 include at least one more multilayer ceramic capacitor (MLCC) and may additionally include other electrical parts such as resistor, diode, transistor and so on. Here, the multilayer ceramic capacitor (MLCC) serves to remove screen noise generated in a camera module, and other electrical parts can be used for improving a module quality. Further, as a semiconductor become highly efficient and highly integrated, the multilayer ceramic capacitor (MLCC) can be implemented to be slim and small by combining a multi-chip package and a three-dimensional stacked structure.

In the image sensor module 30, a specific relationship between the image sensor 33 and the electrical parts 34 arranged and mounted on the FPCB 31 is shown in FIGS. 3 and 4. By reference to the window 32 formed in the FPCB 31, the electrical parts 34 including multilayer ceramic capacitors are mounted on the upper surface of the FPCB 31, and the image sensor 33 is attached on the lower surface thereof. In this case, the electrical parts 34 are mounted so as to be positioned inside the surface on which the image sensor 33 is attached, that is, between the window 32 and the outer peripheral surface of the image sensor 33. Then, the electrical parts 34 are included in the housing 20 when the image sensor module 30 is coupled to the housing 20.

Method of Manufacturing Camera Module

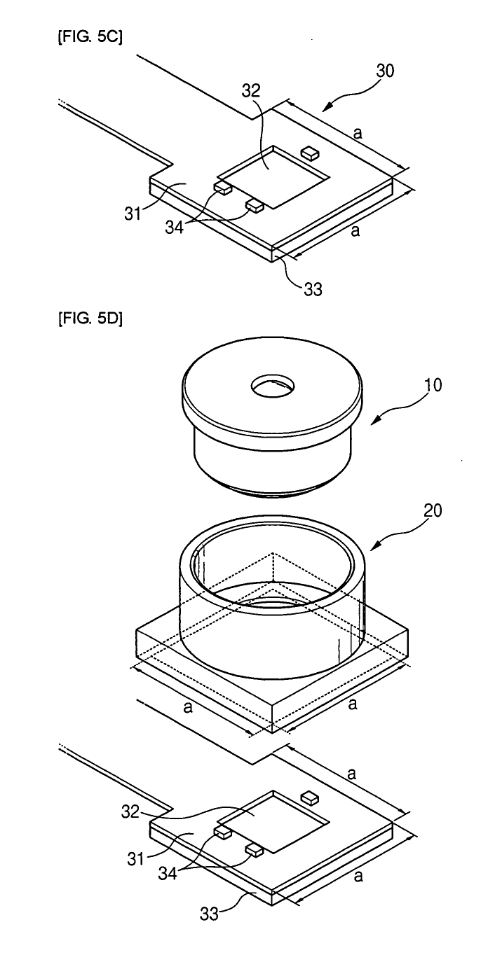

Hereinafter, a method of manufacturing a camera module according to the present invention will be described with reference to FIG. 5.

FIG. 5 is a process diagram illustrating the method of manufacturing a camera module according to the invention. The method is roughly divided into manufacturing an image sensor module and coupling and attaching the manufactured image sensor module to the housing including the lens section.

First, in manufacturing the image sensor module, an image sensor wafer is cut so as to prepare a unit image sensor having a predetermined size (a×a). At this time, the wafer is cut so that cutting tolerance of the unit image sensor 33 is less than 20 μm in a width direction.

Then, the FPCB 31 having the same size (a×a) as the image sensor 33 is prepared. In the FPCB 31, the window 32 having a predetermined size is formed, through which light received from the condensing lens of the lens section 10 can be transmitted.

Then, the image sensor 33 is attached on the rear surface of the FPCB 31. As a flip-chip bonding method for attaching the image sensor 33 on the rear surface of the FPCB 31, the following methods can be used. A first method is where an anisotropic conductive film (ACF) is inserted between the rear surface of the FPCB 31 and the image sensor 33 and is then pressed. A second one is where a non-conductive paste (NCP) is put between the rear surface of the FPCB 31 and the image sensor 33 and is then pressurized. Further, a method using an ultrasonic wave can be also used. Through the above processes, the image sensor module 30 which is coupled to the housing 20 is completely manufactured.

Meanwhile, if an IR filter for cutting infrared rays from the incident light passing through the lens section 10 is not mounted inside the housing 20, an IR filter having such a size as to cover the window 32 can be attached on a surface (upper surface) opposite to the rear surface of the FPCB 31 of the manufactured image sensor module 30. The IR filter, receiving only visible light from the incident light passing through the lens section, does not serve as a guide for coupling with the housing. Therefore, the size thereof does not need to be the same as that of the coupling portion of the housing.

If a double-sided FPCB or RFPCB is used as the FPCB 31, a process can be added, in which at least one more electrical part 34 such as multilayer ceramic capacitor is mounted on a surface opposite to the rear surface of the FPCB 31 of the image sensor module, or preferably, between the window 32 and the outer peripheral surface of the image sensor 33. As a method of attaching the multilayer ceramic capacitor 34 on the surface opposite to the rear surface of the FPCB 31, solder cream is coated on a portion on which the multilayer ceramic capacitors 34 are to be attached, and the multilayer ceramic capacitors 34 are then attached through a hardening process. Preferably, the method using solder cream is used, because the cost thereof is cheaper than other methods.

Next, coupling and attaching the manufactured image sensor module 30 to the housing 20 including the lens section 10 is performed as follows.

The image sensor module 30 is coupled and attached to the inner peripheral surface (a×a) of the lower opening of the housing 20 supporting the lens section 10 from the direction (upper direction) opposite to the rear surface of the FPCB 31 having the image sensor 33 attached. At this time, the image sensor module 30 is closely attached to the position determining section formed on the inner peripheral surface of the hosing 20 at the lower opening.

Here, the coupling is performed with the outer peripheral surface of the image sensor 33 being set to a guide surface. As such, since the coupling between the image sensor module 30 and the housing 20 is performed with the outer peripheral surface of the image sensor 33 being set to a guide surface, the IR filter size tolerance and IR filter position tolerance in the conventional COF packaging method are removed, which makes it possible to prevent optical axis shifting, tilting, and rotation in which an optical axis passing through the lens section is separated at a predetermined distance from the pixel center of the image sensor. Further, since the coupling is performed with the outer peripheral surface of the image sensor 33 being set to a guide surface, it is possible to implement a camera module width which is larger only by 300 μm at a maximum than the image sensor. Furthermore, the process of attaching an IR filter is not essential, different from in the related art. Therefore, it is possible to reduce the number of manufacturing processes, thereby enhancing productivity.

Further, the attaching can be performed by an adhesive coated on the interface between the image sensor module 30 and the housing 20. Through the above processes, the camera module is completely manufactured.

Meanwhile, when the image sensor module 30 is assembled into the housing 20, the lens section 10, into which the aperture, the condensing lens and the like are assembled, may be previously mounted from the upper opening of the housing 20. Alternately, the lens section 10 may be mounted after the image sensor module 30 is assembled into the housing 20.

According to the image sensor module, the camera module using the same, and the method of manufacturing the camera module, the optical axis passing through the lens section is caused to be accurately positioned in the receiving section of the image sensor, thereby preventing optical axis shifting, tilting, and rotation. Therefore, it is possible to reduce percent defective related to high resolution and resolution. Further, the size of the module can be reduced, thereby achieving the miniaturization and improving the utilization of space. Furthermore, the number of manufacturing processes is reduced, thereby improving productivity.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. An image sensor module comprising:
a flexible printed circuit board (FPCB) having a window; and
an image sensor that is formed to have the same size as the width of the FPCB and is attached on one surface of the FPCB, the image sensor including a light receiving section, which receives light passing through the window, and a signal processing section which processes signals generated by the light receiving section.

2. The image sensor module according to claim 1,
wherein the FPCB is a rigid flexible printed circuit board (RFPCB) or a double-sided flexible printed circuit board (FPCB).

3. The image sensor module according to claim 2,
wherein at least one more electrical part is attached on the other surface of the FPCB having the image sensor attached thereon.

4. The image sensor module according to claim 3,
wherein the electrical parts are mounted so as to be positioned between the window and the outer peripheral surface of the image sensor.

5. The image sensor module according to claim 3,
wherein the electrical parts include at least one more multilayer ceramic capacitor (MLCC).

6. A camera module comprising:
a lens section;
a housing supporting the lens section; and
an image sensor module composed of an FPCB that has the substantially same size of an outer peripheral surface as the inner peripheral surface of the lower opening of the housing and is attached on the inner peripherals surface of the lower opening of the housing; and an image sensor module that is formed to have the same size as the width of the FPCB having a window and is attached on the rear surface of the FPCB.

7. The camera module according to claim 6,
wherein the FPCB is a RFPCB or double-sided FPCB.

8. The camera module according to claim 7,
wherein at least one more electrical part is attached on a surface opposite to the rear surface of the FPCB having the image sensor attached thereon.

9. The camera module according to claim 8,
wherein the electrical parts are mounted so as to be positioned between the window and the outer peripheral surface of the image sensor.

10. The camera module according to claim 8,
wherein the electrical parts include at least one more multilayer ceramic capacitor (MLCC).

11. The camera module according to claim 6 further including
an IR cut filter that is mounted inside the housing in order to receive only visible light from the incident light passing through the lens section.

12. The camera module according to claim 6 further including
an IR cut filter that is attached on a surface opposite to the rear surface of the FPCB having the image sensor attached thereon, in order to receive only visible light from the incident light passing through the lens section.

13. A method of manufacturing a camera module comprising:
attaching an image sensor on the rear surface of an FPCB provided with a window, the image sensor having the substantially same size as the width of the FPCB, in order to provide an image sensor module; and
coupling and attaching the image sensor module to the inner peripheral surface of a lower opening of a housing supporting a lens section from the direction opposite to the rear surface of the FPCB having the image sensor attached, with the outer peripheral surface of the image sensor being set to a guide surface.

14. The method according to claim 13,
wherein a RFPCB or double-sided FPCB is used as the FPCB.

15. The method according to claim 14 further including,
prior to coupling the image sensor module to the inner peripheral surface of the lower opening of the housing supporting the lens section, mounting at least one more electrical part on the surface opposite to the rear surface of the FPCB having the image sensor attached, such that at least one more electrical part is positioned between the window and the outer peripheral surface of the image sensor.

16. The method according to claim 13 further including,
prior to coupling the image sensor module to the inner peripheral surface of the lower opening of the housing supporting the lens section, mounting an IR cut filter in the housing, in order to receive only visible light from the incident light passing through the lens section.

17. The method according to claim 13 further including,
prior to coupling the image sensor module to the inner peripheral surface of the lower opening of the housing supporting the lens section, attaching an IR cut filter on the surface opposite to the rear surface of the FPCB having the image sensor attached, in order to receive only visible light from the incident light passing through the lens section.

18. The method according to claim 13,
wherein attaching the image sensor on the rear surface of the FPCB is performed by any one of a method in which an anisotropic conductive film (ACF) is inserted between the rear surface of the FPCB and the image sensor and is then pressed, a method in which a non-conductive paste (NCP) is put between the rear surface of the FPCB and the image sensor and is then pressurized, and a method using an ultrasonic wave.
